(19) United States
(12) Patent Application Publication
(10) Pub. No.: US 2023/0118440 A1
(43) Pub. Date: Apr. 20, 2023

(54) FOLDABLE DISPLAY SCREENS

(71) Applicant: Hewlett-Packard Development Company, L.P., Spring, TX (US)

(72) Inventors: Chien-Kuo Lee, Taipei City (TW); Chang-I Chen, Taipei City (TW)

(73) Assignee: Hewlett-Packard Development Company, L.P., Spring, TX (US)

(21) Appl. No.: 17/801,534

(22) PCT Filed: Feb. 24, 2020
(86) PCT No.: PCT/US2020/019515

§ 371 Date: Aug. 23, 2022

(51) Int. Cl. H05K 5/02

(52) U.S. Cl. CPC H05K 5/0226

(57) ABSTRACT

Examples of devices with foldable display screens are described. In an example, the foldable display screen of the device includes a first portion, a second portion, and an intermediary portion between the first portion and the second portion. The device further includes a hinge joint coupled to the first portion and the second portion to fold the first portion and the second about the intermediary portion. Further, the device includes an actuating block abutting the intermediary portion and the hinge joint. The actuating block, in response to receiving a pressing force from a user on the intermediary portion above the actuating block, is to cause the hinge joint to operate and fold the foldable display screen.

### BACKGROUND

Display devices, such as smart phones or tablets may include foldable display screens. In such display devices, the display screen is coupled to a hinge joint. The hinge joint enables folding of the display screen.

### BRIEF DESCRIPTION OF FIGURES

The detailed description is provided with reference to the accompanying figures, wherein:

FIG. 1(a) illustrates a schematic top view of a device with a foldable display screen, according to an example;

FIG. 1(b) illustrates a side view of the device of FIG. 1(a);

FIG. 2 illustrates a schematic view of a device with a foldable display screen, according to an example;

FIG. 3 illustrates a schematic view of a device with a foldable display screen in a folded state, according to an example;

FIG. 4 illustrates a schematic view of a device with a foldable display screen, according to an example;

FIG. 5 illustrates a schematic view of a device with a foldable display screen in a folded state, according to an example;

FIG. 6 illustrates a schematic view of a device with a foldable display screen, according to an example; and

FIG. 7 illustrates a schematic view of the device of FIG. 6 in a folded state.

### DETAILED DESCRIPTION

The present subject matter describes example devices with foldable display screens. In the example devices described herein, trace formations on the foldable display screen, which may otherwise be formed due to pressing of the display screen for the purpose of folding the screen, are eliminated.

In an example, the device includes a foldable display screen and a hinge joint. The foldable display screen may be divided into three portions, namely a first portion, a second portion, and an intermediary portion. The intermediary portion is between the first portion and the second portion. The first portion and the second portion folds over the intermediary portion for folding the foldable display screen. The hinge joint is coupled to the first portion and the second portion of the foldable display screen. The hinge joint may move the first portion and the second portion of the foldable display screen about a central axis of the intermediary portion for folding the foldable display screen.

Further, the device includes an actuating block placed between the hinge joint and the foldable display screen. A first side of the actuating block abuts the intermediary portion of the foldable display screen and a second side of the actuating block, opposite to the first side, abuts the hinge joint. In an example, the first side of the actuating block may abut the intermediary portion of the foldable display screen at the central axis of the intermediary portion. The actuating block fills a gap between the foldable display screen and the hinge joint.

To initiate folding of the display screen of the device, a user may press the intermediary portion above the actuating block. The actuating block abutting the intermediary portion accordingly receives a pressing force and transfers the pressing force to the hinge joint. As a result, the hinge joint operates and moves the first portion and the second portion of the foldable display screen about the central axis of the intermediary portion of the foldable display screen for folding the display screen.

Due to the absence of a gap between the foldable display screen and the hinge joint, the foldable display screen does not experience a trace formation thereon even after a prolonged usage of the device. Thus, the aesthetic appeal, the display performance, and the touch sensitivity (if applicable) of the foldable display screen and the device are retained for a long time.

The following detailed description refers to the accompanying drawings. Wherever possible, the same reference numbers are used in the drawings and the following description to refer to the same or similar parts. While several examples are described in the description, modifications, adaptations, and other implementations are possible. Accordingly, the following detailed description does not limit the disclosed examples. Instead, the proper scope of the disclosed examples may be defined by the appended claims.

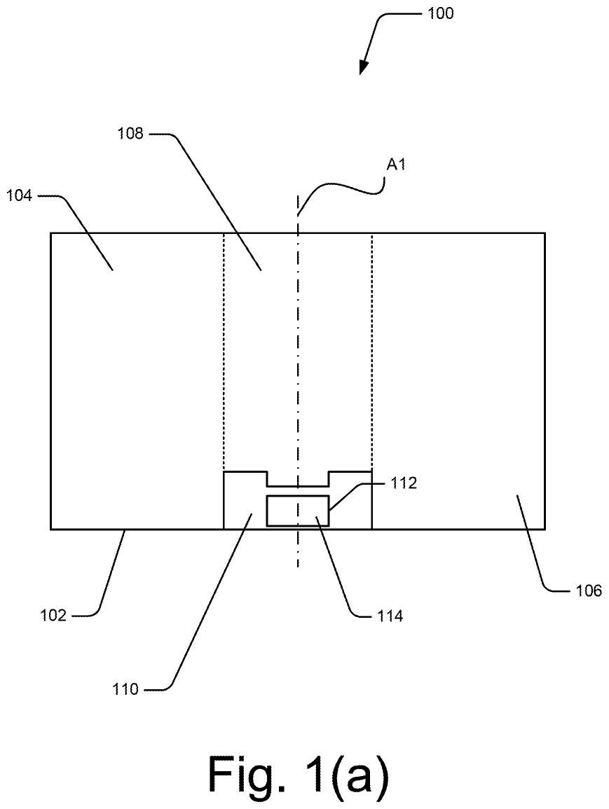

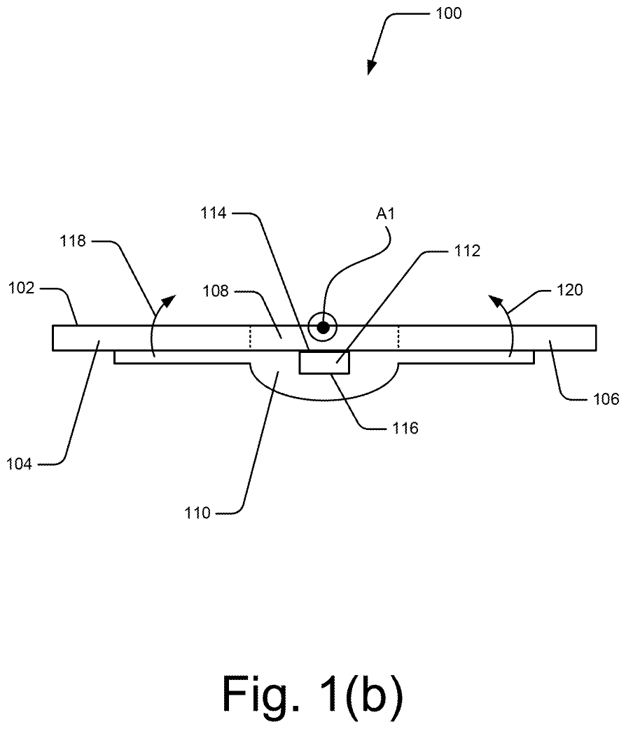

FIG. 1(a) illustrates a schematic top view of a device 100, according to an example. The device 100 may be a display device, for example, a smart phone or a tablet. The device 100 includes a foldable display screen 102. A foldable display screen 102 may be folded when the device 100 is not in use and retracted from the folded state when the device 100 is to be used in order to allow a user of the device 100 to have a large display. In an example, the foldable display screen 102 may be touch-sensitive.

The foldable display screen 102 may be separated into a first portion 104, a second portion 106, and an intermediary portion 108. The intermediary portion 108 is present between the first portion 104 and the second portion 106. The intermediary portion 108 is a region of a foldable display screen 102, about which the first portion 104 and the second portion 106 fold to bring the foldable display screen 102 to the folded state. The foldable display screen 102 has a central axis A1 passing through the intermediary portion 108 of the foldable display screen 102. In an example, the central axis A1 of the intermediary portion 108 may be understood as a central axis of the foldable display screen 102.

Further, the device 100, as shown, includes a hinge joint 110 coupled to the first portion 104 and the second portion 106 of the foldable display screen 102. A hinge joint 110 is a mechanical component that enables folding of a foldable display screen 102 by moving the first portion 104 and the second portion 106 of the foldable display screen 102 about the central axis A1 of the intermediary portion 108.

As shown in the device 100 of FIG. 1(a), an actuating block 112 is coupled to the hinge joint 110. The actuating block 112 has a first side 114 and a second side (visible in FIG. 1(b)). FIG. 1(b) illustrates a side view of the device 100 of FIG. 1(a). The first side 114 of the actuating block 112 abuts the intermediary portion 108 of the foldable display screen 102. Further, the second side 116 of the actuating block 112 abuts the hinge joint 110. The actuating block 112 is a structure that acts as a gap filler between the intermediary portion 108 of the foldable display screen 102 and the hinge joint 110. In an example, the actuating block 112 is fixedly coupled to the intermediary portion 108 of the foldable display screen 102. In an example, the actuating block 112 is glued to the intermediary portion 108 of the foldable display screen 102. In an example, the actuating block 112 is fixedly coupled at the central axis A1 of the intermediary portion 108 of the foldable display screen 102. Although, the hinge joint 110 and the actuating block 112 are shown in FIGS. 1(a) and 1(b) at one end of the device 100, in an example, a device may include two hinge joints and two actuating blocks, with one hinge joint and one actuating block at each end of the device 100.

When the user of the device 100 intends to fold the device 100, the user may press the intermediary portion 108 above the actuating block 112. In response to receiving a pressing force, the actuating block 112 may cause the hinge joint 110 to operate and move the first portion 104 and the second portion 106 about the central axis A1 of the intermediary portion 108 for folding the foldable display screen 102. The direction of movement of the first portion 104 about the central axis A1 of the intermediary portion 108 is indicated by arrow 118 in FIG. 1(b) and the direction of movement of the second portion 106 about the central axis A1 of the intermediary portion 108 is indicated by arrow 120 in FIG. 1(b). The first portion 104 and the second portion 106 of the foldable display screen 102 move closer to each other about the central axis A1 for folding the foldable display screen 102. It be understood that the central axis A1 is depicted as a point to indicate an axis perpendicular to the plane in which FIG. 1(b) is made.

The device 100 has no gap between the hinge joint 110 and the intermediary portion 108 of the foldable display screen 102 due to the presence of the actuating block 112 therebetween. As a result, when the intermediary portion 108 above the actuating block 112 receives the pressing force from the user, there is no space for the intermediary portion 108 of the foldable display screen 102 to bulge-in to abut the hinge joint 110. Due to absence of the gap between the hinge joint 110 and the intermediary portion 108, any trace formation on the foldable display screen 102 is not possible even after usage of the device 100 for a prolong period. Thus, aesthetic appeal of the foldable display screen 102 is retained.

Further, in the device 100, effectiveness of the display performance of the foldable display screen 102 is retained for a long time. If the foldable display screen 102 is touch-sensitive, touch-sensitivity of the foldable display screen 102 retains same effectiveness even after a prolonged period of usage of the device 100.

Further, abutment of the actuating block 112 both with the foldable display screen 102 and the hinge joint 110 enables provisioning of a constant moving force (originated by a pressing force from the user) via the actuating block 112 to the hinge joint 110 during the folding of the foldable display screen 102. Due to the constant moving force during the folding of the foldable display screen 102, an angle between a plane in which the first portion 104 lies and the central axis A1 and an angle between a plane in which the second portion 106 lies, and the central axis A1 are the same at any point during the folding. Thereby, a uniform folding of the first portion 104 and the second portion 106 about the central axis A1 may be achieved.

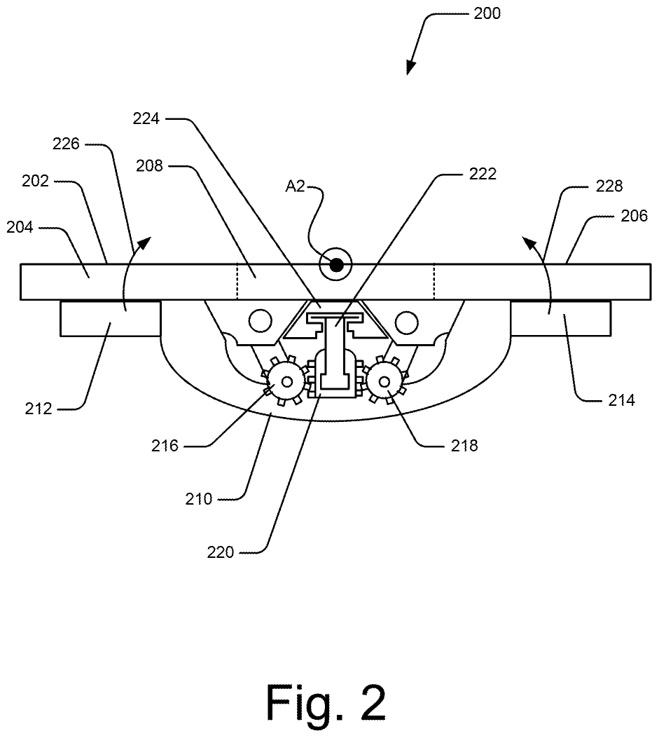

Two examples of the device 100 are further described in detail with respect to the description of FIGS. 2 to 7.

FIG. 2 illustrates a schematic view of a device 200, according to an example. The device 200 includes a display screen 202 similar to the foldable display screen 102 of FIGS. 1(a) and 1(b). The display screen 202 may be folded by a user of the device 200, when the device 200 is not to be used. The display screen 202 includes a first portion 204, a second portion 206, and an intermediary portion 208 similar to the first portion 104, the second portion 106, and the intermediary portion 108, respectively, of the device 100. The first portion 204 and the second portion 206 are separated by the intermediary portion 208.

In an example, the display screen 202 has a central axis A2, similar to the central axis A1 of the device 100, passing through the intermediary portion 208 of the display screen 202. Like in FIG. 1(b), the central axis A2 is depicted in FIG. 2 as a point to indicate an axis coming out from or going into a plane in which FIG. 2 is made. The central axis A2 of the intermediary portion 208 and a central axis of the display screen 202 may be the same.

Further, the device 200, as shown, includes a hinge joint 210 similar to the hinge joint 110 of FIG. 1(a). The hinge joint 210 is coupled to the first portion 204 and the second portion 206 of the display screen 202 and moves the first portion 204 and the second portion 206 for folding the display screen 202. The hinge joint 210 has a first arm 212 and a second arm 214. The first arm 212 of the hinge joint 210 is coupled to the first portion 204 of the display screen 202. The first arm 212 is to move the first portion 204 of the display screen 202 for folding the display screen 202. The second arm 214 of the hinge joint 210 is coupled to the second portion 206 of the display screen 202. The second arm 214 is to move the second portion 206 of the display screen 202 for folding the display screen 202.

The hinge joint 210, as shown in FIG. 2, further includes a first gear 216 and a second gear 218. The first gear 216 is operably coupled to the first arm 212 of the hinge joint 210. The second gear 218 is operably coupled to the second arm 214 of the hinge joint 210. The gear 216, 218 is a rotating wheel, having teeth on periphery thereof, which may rotate, in response to a pressing force received on the display screen, to move the first portion 204 and the second portion 206 about the central axis A2 of the intermediary portion 208.

Further, the hinge joint 210 includes a toothed rack 220 meshable with the first gear 216 and the second gear 218 for folding the display screen 202. The toothed rack 220 may enable movement of the first arm 212 and the second arm 214 of the hinge joint 210 about the central axis A2 of the intermediary portion 208. The toothed rack 220 is a structure having teeth meshable with a gear to convert linear motion to a rotational motion. In an example, the first gear 216 and the toothed rack 220 may form one rack and pinion arrangement, and the second gear 218 and the toothed rack 220 may form another rack and pinion arrangement.

Further, the hinge joint 210 of the device 200 includes a pin 222 having a first end coupled with the toothed rack 220 and having a second end abutting an actuating block 224 of the device 200. The actuating block 224 may be similar to the actuating block 112 of the device 100. The actuating block 224 is coupled to the intermediary portion 208 of the display screen 202. In an example, the actuating block 224 is fixedly coupled at a region of the display screen 202 under the central axis A2 of the intermediary portion 208.

The pin 222 of the hinge joint 210 may receive a pressing force applied from the user, for folding the display screen 202, on the intermediary portion 208 above the actuating block 224. The pin 222 transfers the received pressing force to the toothed rack 220. The toothed rack 220, upon receiving the transferred pressing force, meshes with the first gear 216 and the second gear 218 and rotates the first gear 216 and the second gear 218 to fold the first portion 204 of the display screen 202 over the second portion 206 of the display screen 202. For folding the first portion 204 of the display screen 202 over the second portion 206, the first portion 204 of the display screen 202 moves in a direction as indicated by arrow 226 in FIG. 2. Simultaneously, the second portion 206 of the display screen 202 moves in a direction as indicated by arrow 228 in FIG. 2.

The presence of the actuating block 224 between the intermediary portion 208 of the display screen 202 and the pin 222 prevents creation of a gap between the intermediary portion 208 and the pin 222. Therefore, the pressing force is directly transmitted to the pin 222 via the actuating block 224, while the display screen 202 does not experience bulging. Further, the actuating block 224 is in abutment with the hinge joint 210 during the complete folding of the display screen 202, therefore a constant moving force is applied onto the hinge joint 210 during the folding of the display screen 202.

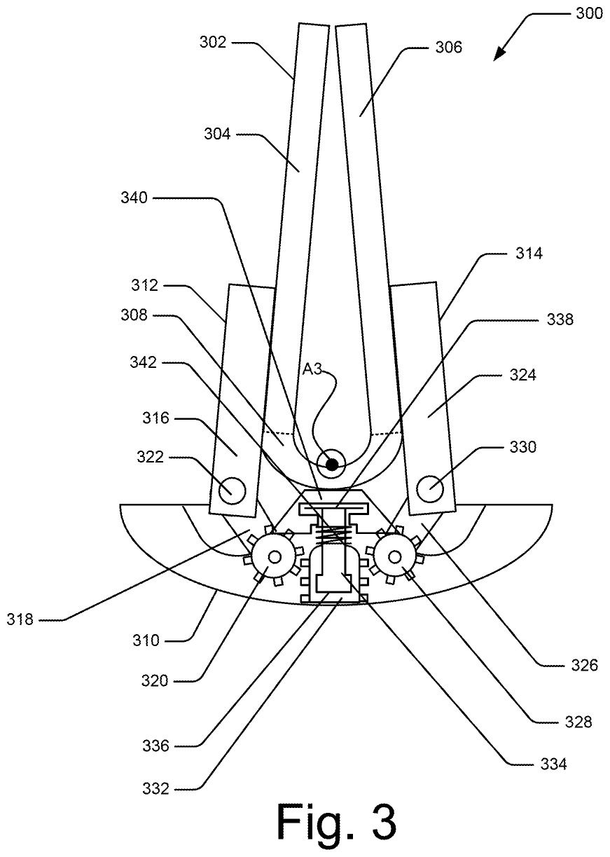

FIG. 3 illustrates a schematic view of a device 300 in a folded state, according to an example. The device 300 may be similar to the device 200 of FIG. 2. As shown in FIG. 3, a display screen 302 of the device 200 is foldable and is similar to the display screen 202 of FIG. 2. A first portion 304, a second portion 306, and an intermediary portion 308 form the display screen 302. The first portion 304 is similar to the first portion 204 of FIG. 2. The second portion 306 is similar to the second portion 206 of FIG. 2. The intermediary portion 308 is similar to the intermediary portion 208 of FIG. 2. The intermediary portion 308 is placed between the first portion 304 and the second portion 306. The intermediary portion 308 of the display screen 302 has a central axis A3, similar to the central axis A2 of FIG. 2.

The device 300 has a hinge joint 310. The hinge joint 310, as shown in FIG. 3, is coupled to the first portion 304 and the second portion 306 of the display screen 302, and is similar to the hinge joint 210 of FIG. 2. A first arm 312, similar to the first arm 212 of FIG. 2, and a second arm 314, similar to the second arm 214 of FIG. 2, are included in the hinge joint 310.

The first arm 312 includes a first supporting member 316 and a first linking rod 318. The first supporting member 316 is coupled with the first portion 304 of the display screen 302. A first end of the first linking rod 318 is operably coupled to a first gear 320 similar to the first gear 216 of FIG. 2. A second end of the first linking rod 318 is pivoted to the first supporting member 316 via a first connecting pin 322. The second arm 314 of the hinge joint 310 includes a second supporting member 324 and a second linking rod 326. The second supporting member 324 is coupled with the second portion 306 of the display screen 302. A first end of the second linking rod 326 is operably coupled to a second gear 328 similar to the second gear 218 of FIG. 2. A second end of the second linking rod 326 is pivoted to the second supporting member 324 via a second connector pin 330.

Further, a toothed rack 332, similar to the toothed rack 220 of FIG. 2, is shown in FIG. 3 in a meshed state with the first gear 320 and the second gear 328. As shown, the hinge joint 310 includes a pin 334 similar to the pin 222 of FIG. 2. The pin 334 has a first end 336 and a second end 338. The first end 336 of the pin 334 is coupled to the toothed rack 332. The second end 338 of the pin 334 is abutting an actuating block 340 of the device 300. The actuating block 340 is similar to the actuating block 224 of FIG. 2. The actuating block 340 is fixedly coupled to the intermediary portion 308 of the display screen 302. The actuating block 340 is abutting the display screen 302 and the hinge joint 310, thereby eliminating a gap between the display screen 302 and the hinge joint 310.

To initiate the folding of the display screen 302, the user of the device 300 applies a pressing force above the actuating block 340 on the intermediary portion 308. The applied pressing force is transferred to the actuating block 340 and further transferred to the pin 334 of the hinge joint 310. The pin 334 transfers the pressing force to the toothed rack 332. In response to receiving the pressing force, the toothed rack 332 meshes with the first gear 320 and the second gear 328 of the hinge joint 310. As a result of the meshing, the first gear 320 rotates in a clockwise direction and moves the first linking rod 318 in a direction opposite to the clockwise direction of the first gear 320. Such a movement of the first linking rod 318 moves the first supporting member 316 for folding the first portion 304 of the display screen 302 with respect to the second portion 306 of the display screen 302.

Simultaneously, as a result of the meshing, the second gear 328 rotates in an anti-clockwise direction and moves the second linking rod 326 in a direction opposite to the anti-clockwise direction of the second gear 328. Such a movement of the second linking rod 326 moves the second supporting member 324 for folding the second portion 306 of the display screen 302 with respect to the first portion 304 of the display screen 302. Further, after the initial movement of the first portion 304 and the second portion 306 towards each other, the first portion 304 and the second portion 306 of the display screen 202 may be completely folded by the user.

In an example, in the hinge joint 310, a resilient element 342 is disposed around the pin 334. The resilient element 342 is positioned between the actuating block 340 and the toothed rack 332 in a compressed state. The compressed state of the resilient element 342 keeps the actuating block 340 in a default position with respect to the toothed rack 332 and assists in providing a constant moving force to the hinge joint 310. The resilient element 342 may be one of a spring and an elastic element.

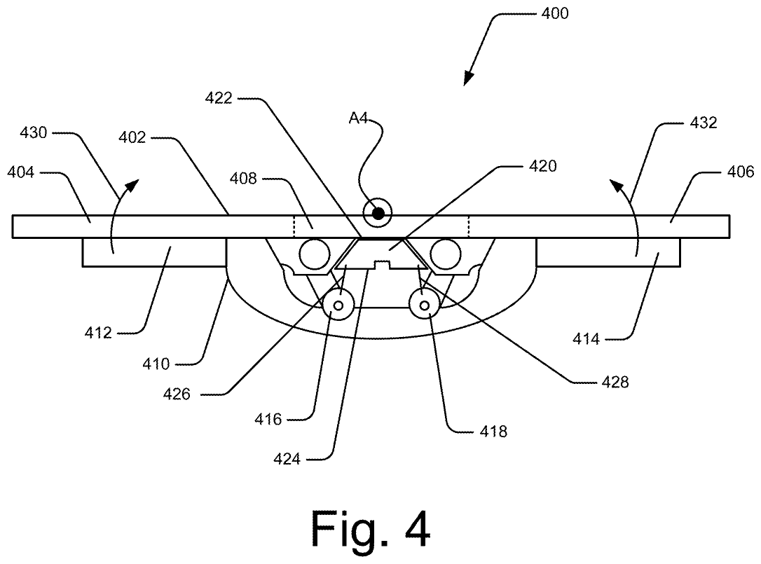

FIG. 4 illustrates a schematic view of a device 400, according to an example. The device 400 is similar to the device 100 of FIGS. 1(a) and 1(b). The device 400 includes a display screen 402, which may be folded when the device 400 is not in use or when a user of the device 400 intends to do so. The display screen 402 includes a first portion 404, a second portion 406, and an intermediary portion 408 similar to the first portion 104, the second portion 106, and the intermediary portion 108, respectively, of foldable display screen 102. The intermediary portion 408, between the first portion 404 and the second portion 406, has a central axis A4 passing therethrough. The central axis A4 may be similar to the central axis A1 of FIGS. 1(a) and 1(b).

The device 400 includes a hinge joint 410, similar to the hinge joint 110 of FIG. 1(a) and coupled to the first portion 404 and the second portion 406. The hinge joint 410 includes a first arm 412 coupled with the first portion 404 of the display screen 402. The first portion 404 is moved by the first arm 412 for folding the display screen 402. The hinge joint 410 further includes a second arm 414 coupled to the second portion 406 of the display screen 402. The second portion 406 is moved by the second arm 414 for folding the display screen 402.

The hinge joint 410 further includes a first rotating member 416 and a second rotating member 418. The first rotating member 416 is operably coupled to the first arm 412 of the hinge joint 410. The second rotating member 418 is operably coupled to the second arm 414 of the hinge joint 410. The rotating member 416, 418 is a rotating wheel that transfers a pressing force received from a user to the first portion 404 and the second portion 406 of the display screen 402 for folding the display screen 402.

Further, the device 400 includes an actuating block 420. A first side 422 of the actuating block 420 abuts the intermediary portion 408 of the display screen 402, in an example, at the central axis A4. A second side 424 of the actuating block 420 abuts the hinge joint 410. The abutment of the actuating block 420 with the intermediary portion 408 of the display screen 402 and the hinge joint 410 eliminates the possibility of a gap between the display screen 402 and the hinge joint 410.

For abutment of the actuating block 420 with the hinge joint 410, the hinge joint 410 includes a first link 426 and a second link 428. A first end of the first link 426 is operably coupled to the first rotating member 416. A second end of the first link 426 is abutting the actuating block 420. In an example, the first link 426 is pivoted with the actuating block 420. Further, a first end of the second link 428 is operably coupled to the second rotating member 418. A second end of the second link 428 is abutting the actuating block 420. In an example, the second link 428 is pivoted with the actuating block 420.

When the folding of the display screen 402 is initiated from a retracted state of the device 400, the actuating block 420 is pressed by the user by applying a pressing force at a region of the intermediary portion 408 above the actuating block 420. The actuating block 420 transfers the pressing force to the first link 426 and the second link 428. The first link 426 and the second link 428, upon receiving the pressing force, rotate the first rotating member 416 and the second rotating member 418, respectively. In an example, the first rotating member 416 may rotate in a clockwise direction and, simultaneously, the second rotating member 418 may rotate in an anti-clockwise direction. Such rotations of the first rotating member 416 and the second rotating member 418 may move the first portion 404 of the display screen 402 in a direction indicated by arrow 430 in FIG. 4 and the second portion 406 of the display screen 402 in a direction indicated by arrow 432 in FIG. 4. The movements of the first portion 404 and the second portion 406 are about the central axis A4 of the intermediary portion 408 of the display screen 402. The movements of the first portion 404 and the second portion 406 of the display screen 402 enable folding of the display screen 402.

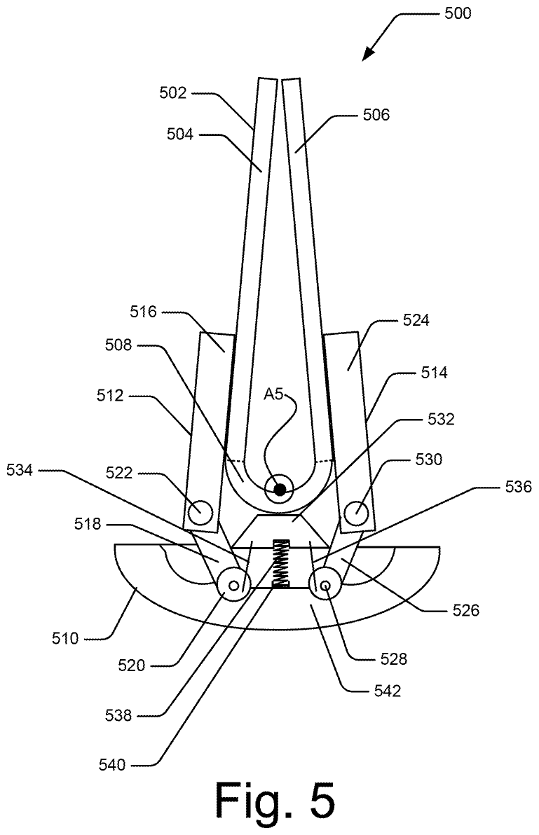

FIG. 5 illustrates a schematic view of a device 500 in a folded state. The device 500 is similar to the device 400 of FIG. 4. As shown in FIG. 5, a display screen 502 of the device 500 is similar to the display screen 402 of the device 400. A first portion 504, a second portion 506, and an intermediary portion 508 of the display screen 502 are similar to the first portion 404, the second portion 406, and the intermediary portion 408, respectively, of the display screen 402 of the device 400. The intermediary portion 508 has a central axis A5, similar to the central axis A4.

Further, a hinge joint 510 of the device 500 is coupled to the display screen 502 to move the first portion 504 and the second portion 506 of the display screen 502 each away from or towards each other. The hinge joint 510 is similar to the hinge joint 410 of FIG. 4. The hinge joint 510 includes a first arm 512 and a second arm 514. The first arm 512 is formed by a first supporting member 516 and a first linking rod 518. The first supporting member 516 is coupled to the display screen 502 at the first portion 504 thereof. The first linking rod 518 at a first end thereof is operably coupled to a first rotating member 520 of the hinge joint 510. The first linking rod 518 at a second end thereof is pivoted to the first supporting member 516 via a first connecting pin 522. The second arm 514 of the hinge joint 510 includes a second supporting member 524 and a second linking rod 526. The second supporting member 524 is coupled with the second portion 506 of the display screen 502. The second linking rod 526 at a first end thereof is operably coupled to a second rotating member 528 of the hinge joint 510. The second linking rod 526 at a second end thereof is pivoted to the second supporting member 524 via a second connector pin 530.

The device 500 further includes an actuating block 532 similar to the actuating block 420. The actuating block 532 is disposed between the intermediary portion 508 of the display screen 502 and the hinge joint 510. The actuating block 532 abuts the intermediary portion 508 on a first side. The actuating block 532 on a second side thereof is coupled to a first link 534 and a second link 536 of the hinge joint 510. The first link 534 and the second link 536 are operably coupled to the first rotating member 520 and the second rotating member 528.

The actuating block 532, in response to application of a press from the user at a region on the intermediary portion 508 above the actuating block 532, receives a force. The received force is transferred to the first link 534 and the second link 536 of the hinge joint 510. As a result, the first rotating member 520 rotates in a clockwise direction and moves the first linking rod 518 in a direction opposite to the clockwise direction of the first rotating member 520. The movement of the first linking rod 518 moves the first supporting member 516 for rotating the first portion 504 of the display screen 502 about the central axis A5 of the display screen 502.

Simultaneously, the second rotating member 528 rotates in an anti-clockwise direction and moves the second linking rod 526 in a direction opposite to the anti-clockwise direction of the second rotating member 528. The movement of the second linking rod 526 moves the second supporting member 524 for rotating the second portion 506 of the display screen 502 about the central axis A5 of the display screen 502.

In an example, the hinge joint 510 includes a bracket 540 disposed on a base frame 542 of the hinge joint 510. The hinge joint 510 further comprises a resilient element 538 positioned between the bracket 540 and the actuating block 532 in a compressed state. The compressed state of the resilient element 538 keeps the actuating block 532 in a default position intact with respect to the first rotating member 520 and the second rotating member 528. The resilient element 538 assists in providing a constant moving force to the hinge joint 510. The resilient element 538 may be one of a spring and an elastic element.

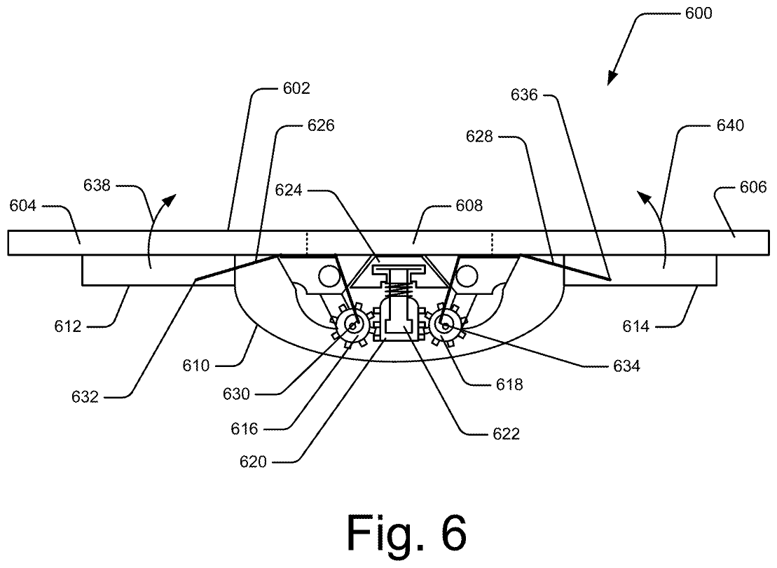

FIG. 6 illustrates a schematic view of a device 600, according to an example. The device 600 is similar to the device 200 as described in FIG. 2. As shown in FIG. 6, the device 600 includes a display screen 602, which is foldable. A first portion 604, a second portion 606, and an intermediary portion 608 of the display screen 602 are similar to the first portion 204, the second portion 206, and the intermediary portion 208, respectively, of the display screen 202.

As shown, the device 600 includes a hinge joint 610 similar to the hinge joint 210. The hinge joint 610 is coupled to the display screen 602. A first arm 612 of the hinge joint 610 couples the display screen 602 with a first gear 616 of the hinge joint 610. Further, a second arm 614 of the hinge joint 610 couples the display screen 602 with a second gear 618 of the hinge joint 610.

Further, the hinge joint 610 includes a toothed rack 620 similar to the toothed rack 220 of FIG. 2. The toothed rack 620 is meshed with the first gear 616 and the second gear 618, as shown. Further, a pin 622 of the hinge joint 610, similar to the pin 222 of FIG. 2, abuts the toothed rack 620 and an actuating block 624 of the device 600. The actuating block 624 is similar to the actuating block 224. The actuating block 624 of FIG. 6 may be coupled to the display screen 602 in a fixed manner.

Further, the device 600 includes a first cable 626 and a second cable 628. In an example, each of the first cable 626 and the second cable 628 is a flexible string. A first end 630 of the first cable 626 is coupled to the first gear 616, and a second end 632 of the first cable 626 is coupled to the first arm 612. A first end 634 of the second cable 628 is coupled to the second gear 618, and the second end 636 of the second cable 628 is coupled to the second arm 614.

For folding the display screen 602, the user of the device 600 applies a pressing force at a region of the intermediary portion 608 above the actuating block 624. This pressing force rotates the first gear 616 and the second gear 618 to fold the first portion 604 of the display screen 602 over the second portion 606 of the display screen 602 in a same manner as described earlier with reference to FIG. 3. For folding the display screen 602, the first portion 604 moves in a direction as indicated by arrow 638 in FIG. 6 and the second portion 606 moves in a direction as indicated by arrow 640 in FIG. 6.

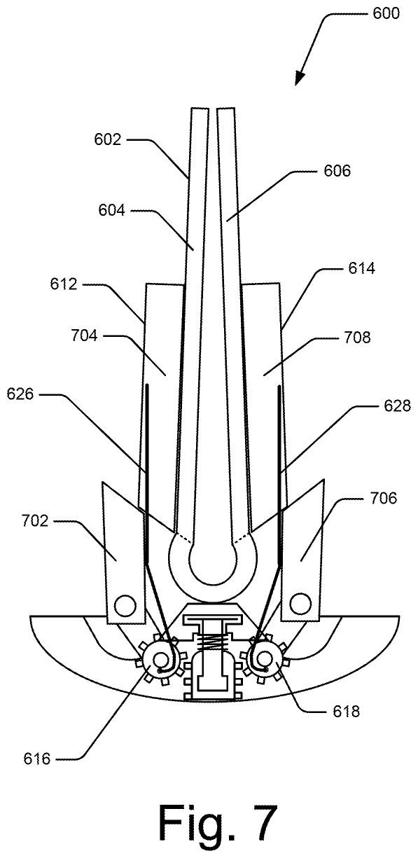

As a result of folding of the first portion 604 over the second portion 606 of the display screen 602, the first cable 626 and the second cable 628 pull the first arm 612 and the second arm 614, respectively, closer to each other. Such a pull enables minimization of the space between the first and second portions 604 and 606 of the display screen 602 that face each other upon folding of the display screen 602, which makes the device 600 aesthetically pleasing in a folded state. An example folded state of the device 600 of FIG. 6 is illustrated in FIG. 7.

As shown in FIG. 7, the first arm 612 includes a first part 702 and a second part 704. The first part 702 is operably coupled with the first gear 616. The second part 704 of the first arm 612 is coupled with the first cable 626 and the first portion 604 of the display screen 602. During the folding of the display screen 602, when the first cable 626 pulls the first arm 612, the second part 704 of the first arm 612 displaces with respect to the first part 702 of the first arm 612 for moving closer to the second portion 606 of the display screen 602.

Similarly, the second arm 614 includes a first part 706 and a second part 708. The first part 706 is operably coupled with the second gear 618. The second part 708 of the second arm 614 is coupled with the second cable 628 and the second portion 606 of the display screen 602. During the folding of the display screen 602, when the second cable 628 pulls the second arm 614, the second part 708 of the second arm 614 displaces with respect to the first part 706 of the second arm 614 for moving closer to the first portion 604 of the display screen 602.

The displacements of the first and second parts of the first arm 612 and the second arm 614 relative to each other allows a maximum width between the first and second portions 604 and 606 of the display screen 602, to be less than a diameter of a curvature formed by the intermediary portion 608 in the folded state of the device 600. In an example, the maximum width is in a range of 3 to 4 mm and the diameter of the curvature is about 6 mm.

Although examples for the present disclosure have been described in language specific to structural features and/or methods, it is to be understood that the appended claims are not limited to the specific features or methods described herein. Rather, the specific features and methods are disclosed and explained as examples of the present disclosure.

We claim:

1. A device comprising:
a foldable display screen having a first portion, a second portion, and an intermediary portion between the first portion and the second portion;
a hinge joint coupled to the first portion and the second portion to move the first portion and the second portion of the foldable display screen about a central axis of the intermediary portion; and
an actuating block abutting at a first side thereof the intermediary portion and abutting at a second side thereof the hinge joint,
the actuating block, in response to receiving a pressing force from a user on the intermediary portion above the actuating block, is to cause the hinge joint to operate to move the first portion and the second portion about the central axis of the intermediary portion.

2. The device as claimed in claim 1, wherein the hinge joint comprises:
a first arm fixedly coupled to the first portion of the foldable display screen;
a second arm fixedly coupled to the second portion of the foldable display screen;
a first gear operably coupled to the first arm;
a second gear operably coupled to the second arm;
a toothed rack meshable with the first gear and the second gear to rotate the first gear and the second gear and move the first arm and the second arm about the central axis of the intermediary portion; and
a pin at a first end thereof coupled to the toothed rack and at a second end thereof abutted with the actuating block.

3. The device as claimed in claim 2, wherein the hinge joint comprises a resilient element disposed around the pin and positioned between the toothed rack and the actuating block, wherein the resilient element is in a compressed state.

4. The device as claimed in claim 3, wherein the resilient element is a spring.

5. The device as claimed in claim 3, wherein the resilient element is an elastic element.

6. The device as claimed in claim 1, wherein the hinge joint comprises:
a first arm fixedly coupled to the first portion of the foldable display screen;
a second arm fixedly coupled to the second portion of the foldable display screen;
a first rotating member operably coupled to the first arm;
a second rotating member operably coupled to the second arm;
a first link at a first end thereof operably coupled to the first rotating member and at a second end thereof abutting the actuating block; and
a second link at a first end thereof operably coupled to the second rotating member and at a second end thereof abutting the actuating block, wherein the first link and the second link are to rotate the first rotating member and the second rotating member, respectively, and move the first arm and the second arm about the central axis of the intermediary portion.

7. The device as claimed in claim 6, wherein the hinge joint comprises:
a base frame;
a bracket disposed on the base frame; and
a resilient element positioned between the bracket and the actuating block, wherein the resilient element is in a compressed state.

8. The device as claimed in claim 7, wherein the resilient element is a spring.

9. A device comprising:
a foldable display screen having a first portion, a second portion, and an intermediary portion between the first portion and the second portion;
a hinge joint coupled to the first portion and the second portion to fold the first portion over the second portion of the foldable display screen about the intermediary portion; and
an actuating block between the intermediary portion and the hinge joint,
the hinge joint comprising:
a first arm coupled to the first portion of the foldable display screen;
a second arm coupled to the second portion of the foldable display screen;
a first gear coupled to the first arm;
a second gear coupled to the second arm;
a toothed rack meshable with the first gear and the second gear; and
a pin at a first end thereof connected with the toothed rack and at a second end thereof abutted with the actuating block,
wherein the actuating block, in response to receiving a pressing force from a user on the intermediary portion above the actuating block, is to cause the pin to move the toothed rack to rotate the first gear and the second gear to fold the first portion over the second portion.

10. The device as claimed in claim 9, wherein the device comprises a spring disposed around the pin and positioned between the toothed rack and the actuating block, wherein the spring is in a compressed state.

11. The device as claimed in claim 10, wherein the device comprises:
a first cable at a first end thereof coupled to the first gear and at a second end thereof coupled to the first arm; and
a second cable at a first end thereof coupled to the second gear and at a second end thereof coupled to the second arm,
wherein, in response to the folding of the first portion over the second portion, the first cable and the second cable are to pull the first arm and the second arm, respectively, closer to each other.

12. The device as claimed in claim 11, wherein the first arm comprises:
a first part operably coupled with the first gear; and
a second part coupled with the first cable and the first portion of the foldable display screen,
wherein the first cable, by the pull of the first arm, is to cause the second part to displace with respect to the first part.

13. The device as claimed in claim 11, wherein the second arm comprises:
a first part operably coupled with the second gear; and
a second part coupled with the second cable and the second portion of the foldable display screen,
wherein the second cable, by the pull of the second arm, is to cause the second part to displace with respect to the first part.

14. A device comprising:
a foldable display screen having a first portion, a second portion, and an intermediary portion between the first portion and the second portion;
a hinge joint coupled to the first portion and the second portion to move the first portion and the second portion of the foldable display screen about a central axis of the intermediary portion; and
an actuating block abutting at a first side thereof the intermediary portion and abutting at a second side thereof the hinge joint,
wherein the hinge joint comprises:
a first arm coupled to the first portion of the foldable display screen;
a second arm coupled to the second portion of the foldable display screen;
a first rotating member operably coupled to the first arm;
a second rotating member operably coupled to the second arm;
a first link at a first end thereof operably coupled to the first rotating member and at a second end thereof abutting the actuating block; and
a second link at a first end thereof operably coupled to the second rotating member and at a second end thereof abutting the actuating block,
wherein the actuating block, in response to receiving a pressing force from a user on the intermediary portion above the actuating block, is to cause the first link and the second link to rotate the first rotating member and the second rotating member, respectively, and to move the first portion and the second portion about the central axis of the intermediary portion.

15. The device as claimed in claim 14, wherein the hinge joint comprises:
a base frame;
a bracket disposed on the base frame; and
a resilient element positioned between the bracket and the actuating block, wherein the resilient element is in a compressed state.
